(19) United States
(12) Patent Application Publication
(10) Pub. No.: US 2025/0268058 A1
(43) Pub. Date: Aug. 21, 2025

(54) COLOR CONVERSION SUBSTRATE, DISPLAY DEVICE INCLUDING THE SAME, AND ELECTRONIC DEVICE INCLUDING THE DISPLAY DEVICE

(71) Applicant: Samsung Display Co., LTD., Yongin-si (KR)

(72) Inventors: KANGMOON JO, Yongin-si (KR); SUNKWANG KIM, Yongin-si (KR); SEUNGHYUN PARK, Yongin-si (KR); HYUNGJIN SONG, Yongin-si (KR); DONG-YOON LEE, Yongin-si (KR); SEONGYOUNG LEE, Yongin-si (KR)

(73) Assignee: Samsung Display Co., LTD., Yongin-si (KR)

(21) Appl. No.: 19/010,893

(22) Filed: Jan. 6, 2025

(30) Foreign Application Priority Data
Feb. 16, 2024 (KR) 10-2024-0022978

(51) Int. Cl. H10K 59/38; H10K 59/80

(52) U.S. Cl. CPC H10K 59/38; H10K 59/8792

(57) ABSTRACT

The color conversion substrate includes a first color filter having a first opening defining a second opening area, a second color filter having a second opening defining a third opening area, and a third color filter having a third opening defining a first opening area, and the first color filter does not overlap a light blocking area surrounding the third opening area.

### CROSS-REFERENCE TO RELATED APPLICATIONS

This application claims priority under 35 U.S.C. § 119 from Korean Patent Application No. 10-2024-0022978 filed on Feb. 16, 2024 in the Korean Intellectual Property Office, the entire contents of which are incorporated herein by reference.

### BACKGROUND

### 1. Technical Field

Implementations of the disclosure relates generally to a color conversion substrate, a display device including the color conversion substrate, and an electronic device including the display device.

### 2. Description of the Related Art

Various patterns may be formed in the display device. A photolithography process may be used to form these patterns. In detail, the photolithography process includes depositing a film, coating photoresist on the film, exposing the photoresist using a mask, developing the exposed photoresist to form a photoresist pattern, and checking the degree of alignment of the photoresist pattern, etc.

### SUMMARY

Embodiments provide a color conversion substrate with improved display quality.

Embodiments provide a display device including the color conversion substrate.

Embodiments provide an electronic device including the display device.

A color conversion substrate according to an embodiment may include an upper substrate including a first opening area, a second opening area adjacent to the first opening area, and a third opening area adjacent to the second opening area, a first color filter disposed on the upper substrate and having a first opening which defines the second opening area, a second color filter disposed on the first color filter and having a second opening which defines the third opening area, and a third color filter disposed on the second color filter and having a third opening which defines the first opening area. The first color filter may not overlap a light blocking area surrounding the third opening area.

In an embodiment, the first color filter may overlap a light blocking area surrounding the second opening area.

In an embodiment, the first color filter may overlap the first opening area and a light blocking area surrounding the first opening area.

In an embodiment, the second color filter may not overlap a light blocking area surrounding the first opening area.

In an embodiment, the second color filter may overlap a light blocking area surrounding the third opening area.

In an embodiment, the second color filter may overlap the second opening area and a light blocking area surrounding the second opening area.

In an embodiment, the third color filter may not overlap a light blocking area surrounding the second opening area.

In an embodiment, the third color filter may overlap a light blocking area surrounding the first opening area.

In an embodiment, the third color filter may overlap the third opening area and a light blocking area surrounding the third opening area.

In an embodiment, the first, second, and third opening areas may be arranged side by side.

In an embodiment, the first color filter may be a blue color filter, the second color filter may be a red color filter, and the third color filter may be a green color filter.

In an embodiment, the color conversion substrate may further include a bank disposed on the upper substrate and overlapping a light blocking pattern surrounding the first to third opening areas.

In an embodiment, the color conversion substrate may further include a first color conversion pattern disposed on the first color filter, the first color conversion pattern accommodated by the bank and including first quantum dots, a second color conversion pattern disposed on the second color filter, the second color conversion pattern accommodated by the bank and including second quantum dots, and a third color conversion pattern disposed on the third color filter, the third color conversion pattern accommodated by the bank and including third quantum dots.

A display device according to an embodiment may include an emission substrate and a color conversion substrate disposed on the emission substrate. The emission substrate may include a lower substrate, a first pixel electrode disposed on the lower substrate, a second pixel electrode disposed on the lower substrate and adjacent to the first pixel electrode, and a third pixel electrode disposed on the lower substrate and adjacent to the second pixel electrode. The color conversion substate may include an upper substrate including a first opening area, a second opening area adjacent to the first opening area, and a third opening area adjacent to the second opening area, a first color filter disposed between the lower substrate and the upper substrate, the first color filter may have a first opening which defines the second opening area, a second color filter disposed between the first color filter and the lower substrate, the second color filter may have a second opening which defines the third opening area, and a third color filter disposed between the second color filter and the lower substrate, the third color filter may have a third opening which defines the first opening area. The first color filter may not overlap a light blocking area surrounding the third opening area.

In an embodiment, the first color filter may overlap a light blocking area surrounding the second opening area.

In an embodiment, the first color filter may overlap the first opening area and a light blocking area surrounding the first opening area.

In an embodiment, the second color filter may not overlap a light blocking area surrounding the first opening area.

In an embodiment, the first color filter may overlap the first pixel electrode, the second color filter may overlap the second pixel electrode, and the third color filter may overlap the third pixel electrode.

In an embodiment, the display device may further include an emission layer disposed on the first to third pixel electrodes and a common electrode disposed on the emission layer.

In an embodiment, the display device may further include an active pattern disposed on the lower substrate, a gate electrode disposed on the active pattern, and a connection electrode disposed on the gate electrode and electrically connected to the active pattern.

An electronic device according to an embodiment may include a display device and a power supply configured to provide power to the display device. The display device may include an emission substrate and a color conversion substrate disposed on the emission substrate. The emission substrate may include a lower substrate, a first pixel electrode disposed on the lower substrate, a second pixel electrode disposed on the lower substrate and adjacent to the first pixel electrode, and a third pixel electrode disposed on the lower substrate and adjacent to the second pixel electrode. The color conversion substate may include an upper substrate including a first opening area, a second opening area adjacent to the first opening area, and a third opening area adjacent to the second opening area, a first color filter disposed between the lower substrate and the upper substrate, the first color filter may have a first opening which defines the second opening area, a second color filter disposed between the first color filter and the lower substrate, the second color filter may have a second opening which defines the third opening area, and a third color filter disposed between the second color filter and the lower substrate, the third color filter may have a third opening which defines the first opening area. The first color filter may not overlap a light blocking area surrounding the third opening area.

Therefore, a display device according to embodiments of the disclosure may include a color conversion substrate on which color filters may be formed. Each of the color filters may define only one adjacent opening area and may not define another opening area. For example, a first color filter may define a second opening area and may not define a third opening area. A second color filter may define the third opening area and may not define a first opening area. A third color filter may define the first opening area and may not define the second opening area. Accordingly, a margin for the width of the bank may be secured, and the pitch between the first to third opening areas may be reduced. Accordingly, the resolution of the display device including the color conversion substrate can be improved.

### BRIEF DESCRIPTION OF THE DRAWINGS

The accompanying drawings, which are included to provide a further understanding of the disclosure and are incorporated in and constitute a part of this specification, illustrate embodiments of the disclosure together with the disclosure.

FIG. 1 is a perspective view illustrating a display device according to an embodiment of the disclosure;

FIG. 2 is a plan view illustrating an emission substrate included in the display device of FIG. 1;

FIG. 3 is a schematic diagram of an equivalent circuit of a pixel included in the emission substrate of FIG. 2;

FIG. 4 is a schematic cross-sectional view illustrating the emission substrate of FIG. 2;

FIG. 5 is a schematic cross-sectional view illustrating a color conversion substrate included in the display device of FIG. 1;

FIG. 6 is a schematic cross-sectional view illustrating the display device of FIG. 1;

FIGS. 7 to 20 are schematic diagrams illustrating a method of manufacturing the color conversion substrate of FIG. 5; and

FIG. 21 is a schematic cross-sectional view illustrating a color conversion substrate included in a display device according to an embodiment of the disclosure;

FIG. 22 is a block diagram illustrating an electronic device according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Illustrative, non-limiting embodiments will be more clearly understood from the following detailed description in conjunction with the accompanying drawings.

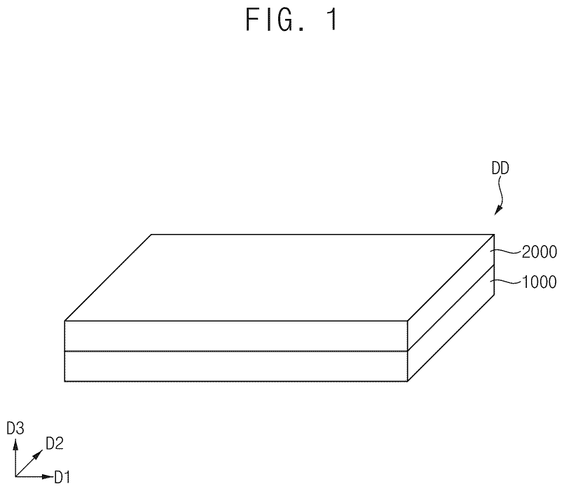

FIG. 1 is a perspective view illustrating a display device according to an embodiment of the disclosure.

Referring to FIG. 1, a display device DD according to an embodiment of the disclosure may include an emission substrate 1000 and a color conversion substrate 2000.

The emission substrate 1000 may generate and may emit light. In an embodiment, the emission substrate 1000 may include at least one pixel circuit and at least one light emitting diode. The pixel circuit may generate a driving current, and the light emitting diode may emit light corresponding to the driving current.

The color conversion substrate 2000 may be disposed on the emission substrate 1000. The color conversion substrate 2000 may convert, transmit, block, and/or absorb the color of light emitted from the emission substrate 1000. Accordingly, the color conversion substrate 2000 may improve color reproducibility of the display device DD.

While manufacturing various patterns included in the color conversion substrate 2000, a photolithography process may be used. For example, the photolithography process may include coating a photoresist, exposing the photoresist using a mask, developing the exposed photoresist to form a photoresist pattern, and checking the degree of alignment of the photoresist pattern.

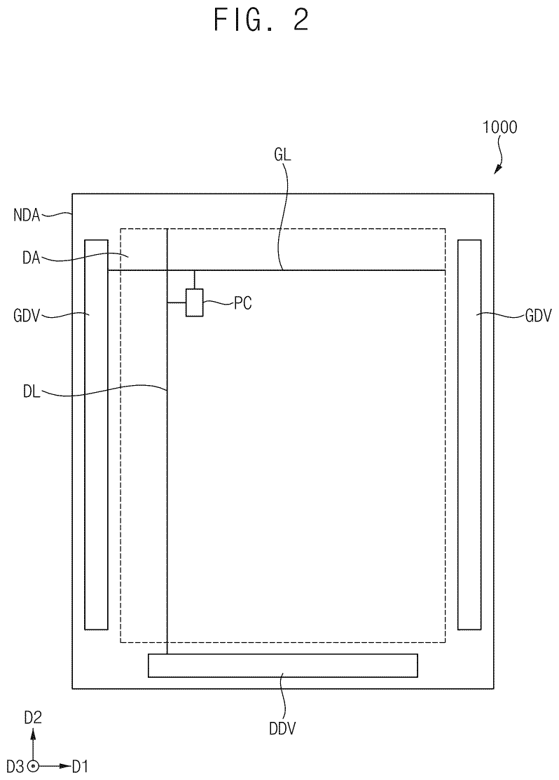

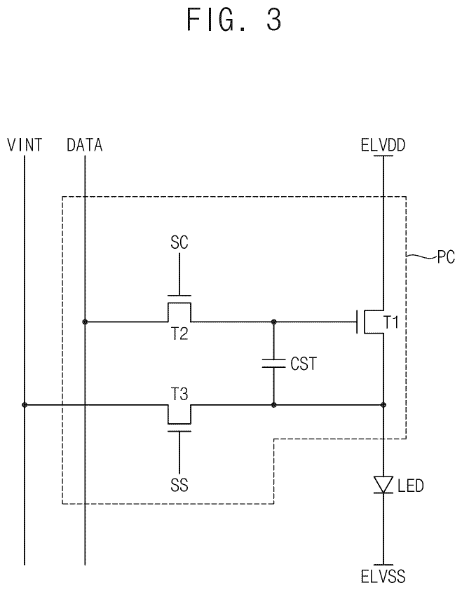

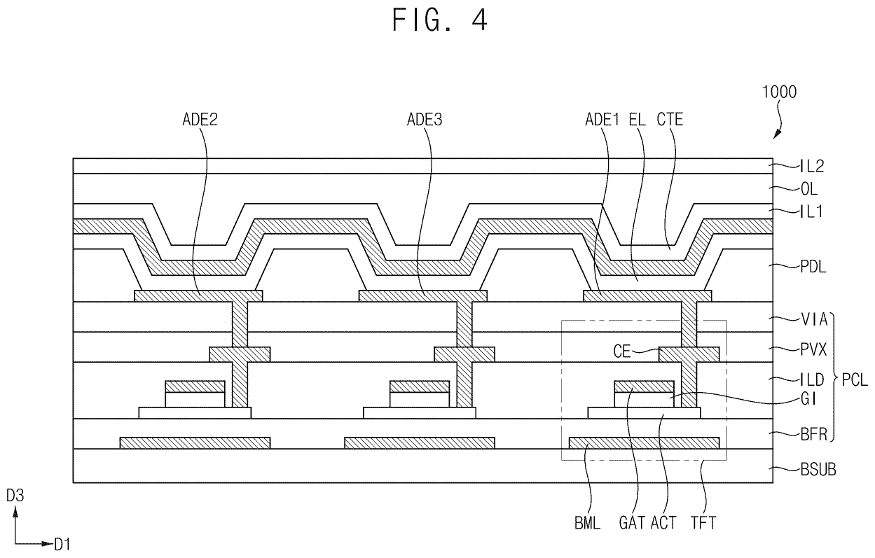

FIG. 2 is a plan view illustrating an emission substrate included in the display device of FIG. 1. FIG. 3 is a schematic diagram of an equivalent circuit of a pixel in the emission substrate of FIG. 2. FIG. 4 is a schematic cross-sectional view illustrating the emission substrate of FIG. 2.

Referring to FIG. 2, the emission substrate 1000 may be divided into a display area DA and a non-display area NDA. An image may be displayed in the display area DA, and the non-display area NDA may be positioned to surround at least a portion of the display area DA.

A pixel circuit PC may be disposed in the display area DA. The pixel circuit PC may be electrically connected to a gate line GL extending in a first direction D1 and a data line DL extending in a second direction D2 intersecting the first direction D1. The pixel circuit PC may generate the driving current.

A gate driver GDV and a data driver DDV may be disposed in the non-display area NDA.

The gate driver GDV may generate a gate signal. The gate signal may be transmitted to the pixel circuit PC through the gate line GL.

The data driver DDV may generate a data voltage. The data voltage may be transmitted to the pixel circuit PC through the data line DL.

Referring to FIG. 3, the pixel circuit PC may include a first transistor T1, a second transistor T2, a third transistor T3, and a storage capacitor CST. The pixel circuit PC may be electrically connected to a light emitting diode LED. The pixel circuit PC may generate the driving current, and the light emitting diode LED may emit light in response to the driving current.

The first transistor T1 may include a gate terminal, a first terminal, and a second terminal. The gate terminal may be electrically connected to the second transistor T2. The first terminal may be provided with a first voltage ELVDD. The second terminal may be electrically connected to the light emitting diode LED. The first transistor T1 may generate the driving current.

The second transistor T2 may include a gate terminal, a first terminal, and a second terminal. The gate terminal may receive a first gate signal SC. The first terminal may be provided with a data voltage DATA. The second terminal may be electrically connected to the first transistor T1. The second transistor T2 may transmit the data voltage DATA in response to the first gate signal SC.

The third transistor T3 may include a gate terminal, a first terminal, and a second terminal. The gate terminal may receive a second gate signal SS. The first terminal may be provided with an initialization voltage VINT. The second terminal may be electrically connected to the light emitting diode LED. The third transistor T3 may transmit the initialization voltage VINT in response to the second gate signal SS.

The storage capacitor CST may include a first terminal and a second terminal. The first terminal may be electrically connected to the gate terminal of the first transistor T1. The second terminal may be electrically connected to the second terminal of the first transistor T1.

The light emitting diode LED may include a first terminal and a second terminal. The first terminal may be electrically connected to the first transistor T1. The second terminal may be provided with a second voltage ELVSS.

Referring to FIG. 4, the emission substrate 1000 may include a lower substrate BSUB, a lower metal pattern BML, a buffer layer BFR, an active pattern ACT, a gate insulating layer GI, a gate electrode GAT, an interlayer insulating layer ILD, a connection electrode CE, a passivation layer PVX, a via insulating layer VIA, a first pixel electrode ADE1, a second pixel electrode ADE2, a third pixel electrode ADE3, a pixel defining layer PDL, an emission layer EL, a common electrode CTE, a first inorganic layer IL1, an organic layer OL, and a second inorganic layer IL2.

The lower metal pattern BML, the active pattern ACT, the gate electrode GAT, and the connection electrode CE may form a transistor TFT.

The lower metal pattern BML, the buffer layer BFR, the active pattern ACT, the gate insulating layer GI, the gate electrode GAT, the interlayer insulating layer ILD, the connection electrode CE, the passivation layer PVX, and the via insulation layer VIA may be defined as a pixel circuit layer PCL.

The lower substrate BSUB may include a transparent or opaque material. In an embodiment, examples of materials that can be used as the lower substrate BSUB may include glass, quartz, and plastic. These can be used alone or in combination with each other. The lower substrate BSUB may be composed of a single layer or multiple layers in combination with each other.

The lower metal pattern BML may be disposed on the lower substrate BSUB. In an embodiment, the lower metal pattern BML may be formed of metal, alloy, conductive metal oxide, transparent conductive material, etc. Examples of materials that can be used as the lower metal pattern BML may include silver (Ag), alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), and indium zinc oxide (IZO). These can be used alone or in combination with each other. The lower metal pattern BML may be composed of a single layer or multiple layers by combining them.

The buffer layer BFR may be disposed on the lower substrate BSUB and may cover the lower metal pattern BML. In an embodiment, the buffer layer BFR may be formed of an inorganic insulating material. Examples of materials that can be used as the inorganic insulating material may include silicon oxide, silicon nitride, silicon oxynitride, and a combination thereof. These can be used alone or in combination with each other. The buffer layer BFR may prevent metal atoms, atoms, or impurities from diffusing from the lower substrate BSUB to the active pattern ACT. The buffer layer BFR may control the rate of heat provision during the crystallization process to form the active pattern ACT.

The active pattern ACT may be disposed on the buffer layer BFR. In an embodiment, the active pattern ACT may be formed of a silicon semiconductor material or an oxide semiconductor material. Examples of the silicon semiconductor material that can be used as the active pattern ACT may include amorphous silicon and polycrystalline silicon. Examples of the oxide semiconductor material that can be used as the active pattern ACT may be InGaZnO (IGZO), InSnZnO (ITZO), etc. Examples of the oxide semiconductor material may further include indium (In), gallium (Ga), tin (Sn), zirconium (Zr), vanadium (V), hafnium (Hf), cadmium (Cd), germanium (Ge), and chromium (Cr), titanium (Ti), and zinc (Zn). These can be used alone or in combination with each other.

The gate insulating layer GI may be disposed on the active pattern ACT. In an embodiment, the gate insulating layer GI may be formed of an insulating material. Examples of insulating materials that can be used as the gate insulating layer GI may include silicon oxide, silicon nitride, and silicon oxynitride. These can be used alone or in combination with each other.

The gate electrode GAT may be disposed on the gate insulating layer GI. In an embodiment, the gate electrode GAT may be formed of metal, alloy, conductive metal oxide, transparent conductive material, etc. Examples of materials that can be used as the gate electrode GAT may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These can be used alone or in combination with each other.

In an embodiment, the gate electrode GAT may be composed of a single layer or multiple layers in combination with each other. For example, the gate electrode GAT may include a titanium layer and a copper layer disposed on the titanium layer. In other words, the gate electrode GAT may have a Ti/Cu structure.

The interlayer insulating layer ILD may be disposed on the buffer layer BFR and the gate insulating layer GI. The interlayer insulating layer ILD may cover the gate electrode GAT. In an embodiment, the interlayer insulating layer ILD may be formed of an insulating material. Examples of insulating materials that can be used as the interlayer insulating layer ILD may include silicon oxide, silicon nitride, and silicon oxynitride. These can be used alone or in combination with each other.

The connection electrode CE may be disposed on the interlayer insulating layer ILD. The connection electrode CE may be in contact with the active pattern ACT. In an embodiment, the connection electrode CE may be formed of metal, alloy, conductive metal oxide, transparent conductive material, etc. Examples of materials that can be used as the connection electrode CE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These can be used alone or in combination with each other.

In an embodiment, the connection electrode CE may be composed of a single layer or multiple layers in combination with each other. For example, the connection electrode CE may include a titanium layer, a copper layer disposed on the titanium layer, and an indium tin oxide layer disposed on the copper layer. In other words, the connection electrode CE may have a Ti/Cu/ITO structure.

The passivation layer PVX may be disposed on the interlayer insulating layer ILD. The passivation layer PVX may cover the connection electrode CE.

In an embodiment, the passivation layer PVX may be formed of an inorganic insulating material. Examples of inorganic insulating materials that can be used as the passivation layer PVX may include silicon oxide, silicon nitride, and silicon oxynitride. These can be used alone or in combination with each other.

In an embodiment, the passivation layer PVX may be omitted.

The via insulation layer VIA may be disposed on the passivation layer PVX. In an embodiment, the via insulation layer VIA may be formed of an organic material. Examples of organic materials that can be used as the via insulating layer VIA may include photoresist, polyacrylic resin, polyimide resin, and acrylic resin. These can be used alone or in combination with each other.

In an embodiment, the passivation layer PVX may be omitted. The via insulation layer VIA may include organic materials and inorganic materials. Examples of materials that can be used as the via insulation layer VIA may include photoresist, polyacrylic resin, polyimide resin, acrylic resin, silicon oxide, silicon nitride, and silicon oxynitride. These can be used alone or in combination with each other.

The first to third pixel electrodes ADE1, ADE2, and ADE3 may be disposed on the via insulating layer VIA. The first to third pixel electrodes ADE1, ADE2, and ADE3 may be electrically connected to corresponding transistors, respectively.

In an embodiment, the first to third pixel electrodes ADE1, ADE2, and ADE3 may be arranged side by side in the first direction D1. In other words, the second pixel electrode ADE2 may be adjacent to the first pixel electrode ADE1 in the first direction D1, the third pixel electrode ADE3 may be adjacent to the first pixel electrode ADE1 in the first direction D1, and the first pixel electrode ADE1 may be adjacent to the third pixel electrode ADE3 in the first direction D1.

In an embodiment, the first to third pixel electrodes ADE1, ADE2, and ADE3 may be formed of metal, alloy, conductive metal oxide, transparent conductive material, etc. Examples of materials that can be used as the first to third pixel electrodes ADE1, ADE2, and ADE3 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), and indium zinc oxide (IZO). These can be used alone or in combination with each other.

In an embodiment, each of the first to third pixel electrodes ADE1, ADE2, and ADE3 may be configured as a single layer or in combination with each other to form a multi-layer structure. For example, each of the first to third pixel electrodes ADE1, ADE2, and ADE3 may have an ITO/Ag/ITO structure.

The pixel defining layer PDL may be disposed on the via insulating layer VIA. An opening exposing the first to third pixel electrodes ADE1, ADE2, and ADE3 may be formed in the pixel defining layer PDL. In an embodiment, the pixel defining layer PDL may be formed of an organic material. Examples of organic materials that can be used as the pixel defining layer PDL may include photoresist, polyacrylic resin, polyimide resin, and acrylic resin. These can be used alone or in combination with each other.

The emission layer EL may be disposed on the first pixel electrode ADE1, the second pixel electrode ADE2, the third pixel electrode ADE3, and the pixel defining layer PDL. In an embodiment, the emission layer EL may be formed in the entire area including the display area DA and the non-display area NDA. For example, the emission layer EL may have a multilayer structure in which multiple layers may be stacked on each other. The emission layer EL may emit light of different colors. In an embodiment, the emission layer EL may be disposed in the opening.

The common electrode CTE may be disposed on the emission layer EL. In an embodiment, the common electrode CTE may be formed of metal, alloy, conductive metal oxide, transparent conductive material, etc.

The first inorganic layer IL1 may be disposed on the common electrode CTE. In an embodiment, the first inorganic layer IL1 may be formed of an inorganic material. Examples of inorganic materials that can be used as the first inorganic layer IL1 may include silicon oxide, silicon nitride, and silicon oxynitride. These can be used alone or in combination with each other.

The organic layer OL may be disposed on the first inorganic layer IL1. In an embodiment, the organic layer OL may be formed of an organic material. Examples of organic materials that can be used as the organic layer OL may include photoresist, polyacrylic resin, polyimide resin, and acrylic resin. These can be used alone or in combination with each other.

The second inorganic layer IL2 may be disposed on the organic layer OL. In an embodiment, the second inorganic layer IL2 may be formed of an inorganic material. Examples of inorganic materials that can be used as the second inorganic layer IL2 may include silicon oxide, silicon nitride, and silicon oxynitride. These can be used alone or in combination with each other.

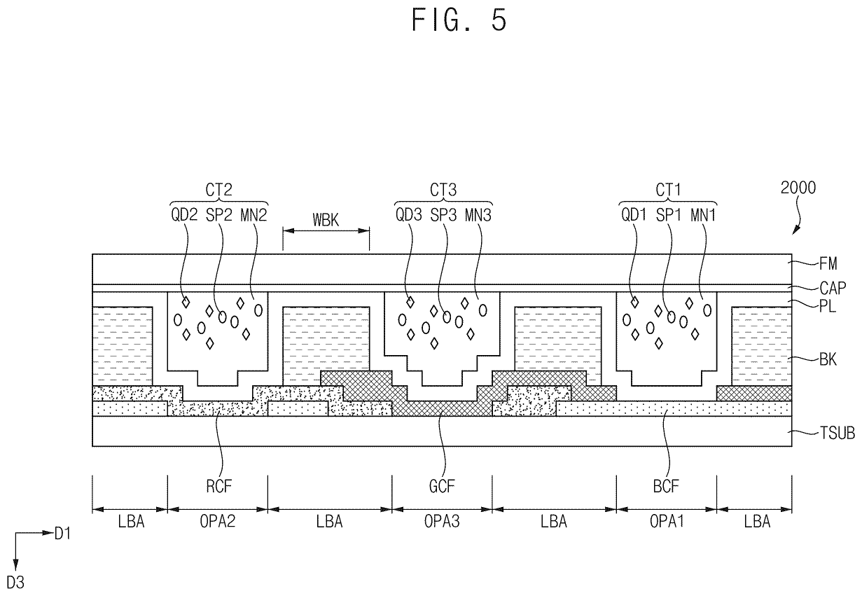

FIG. 5 is a schematic cross-sectional view illustrating a color conversion substrate included in the display device of FIG. 1.

Referring to FIG. 5, the color conversion substrate 2000 may include an upper substrate TSUB, a first color filter BCF, a second color filter RCF, a third color filter GCF, a bank BK, a protective layer PL, a first color conversion pattern CT1, a second color conversion pattern CT2, a third color conversion pattern CT3, a capping layer CAP, and a filler FM.

The upper substrate TSUB may include a transparent or opaque material. In an embodiment, examples of materials that can be used as the upper substrate TSUB may include glass, quartz, and plastic. These can be used alone or in combination with each other. The upper substrate TSUB may be composed of a single layer or multiple layers in combination with each other.

In an embodiment, the upper substrate TSUB may include a first opening area OPA1, a second opening area OPA2, a third opening area OPA3, and a light blocking area LBA.

The first to third opening areas OPA1, OPA2, and OPA3 may be arranged side by side in the first direction D1. For example, the second opening area OPA2 may be adjacent to the first opening area OPA1 in the first direction D1, the third opening area OPA3 may be adjacent to the second opening area OPA2 in the first direction D1, and the first opening area OPA1 may be adjacent to the third opening area OPA3 in the first direction D1.

The light blocking area LBA may be defined in an area excluding (or external to) the first to third opening areas OPA1, OPA2, and OPA3, and may surround the first to third opening areas OPA1, OPA2, and OPA3 in a plan view.

The first color filter BCF may be disposed on the upper substrate TSUB. In an embodiment, the first color filter BCF may be a blue color filter and may transmit only light having a wavelength corresponding to blue. For example, the first color filter BCF may include photoresist, acrylic resin, epoxy resin, polyimide resin, or a combination thereof, and may be patterned through the exposure process described above.

The second color filter RCF may be disposed on the first color filter BCF. In an embodiment, the second color filter RCF may be a red color filter and may transmit only light having a wavelength corresponding to red. For example, the second color filter RCF may include photoresist, acrylic resin, epoxy resin, polyimide resin, or a combination thereof, and may be patterned through the exposure process described above.

The third color filter GCF may be disposed on the second color filter RCF. In an embodiment, the third color filter GCF may be a green color filter and may transmit only light having a wavelength corresponding to green. For example, the third color filter GCF may include photoresist, acrylic resin, epoxy resin, polyimide resin, or a combination thereof, and may be patterned through the exposure process described above.

The bank BK may be disposed on the upper substrate TSUB and may overlap the light blocking area LBA. In an embodiment, the bank BK may be disposed on the third color filter GCF, and may overlap at least two color filters among the first to third color filters BCF, RCF, and GCF. In an embodiment, the bank BK may be disposed on the second color filter RCF and may overlap at least one color filter among the first and second color filters BCF and RCF.

The bank BK may include a light blocking material that blocks or absorbs light. For example, the bank BK may include black pigment, black dye, chromium (Cr), chromium oxide (CrOₓ), chromium nitride (CrNₓ), graphite, a combination thereof, etc.

The protective layer PL may be disposed on the bank BK and may entirely cover the first to third color filters BCF, RCF, and GCF. In an embodiment, the protective layer PL may include an inorganic material. For example, the protective layer PL may include silicon oxide (SiO₂), silicon nitride (SiNₓ), silicon oxynitride (SiON), aluminum oxide (Al₂O₃), titanium dioxide (TiO₂), tantalum oxide (Ta₂O₅), hafnium dioxide (HfO₂), zinc dioxide (ZnO₂), or a combination thereof.

The first color conversion pattern CT1 may be disposed on the first color filter BCF. In an embodiment, the first color conversion pattern CT1 may be accommodated by the bank BK.

In an embodiment, the first color conversion pattern CT1 may include a first monomer MN1, a first quantum dot QD1, and a first scattering particle SP1.

The first quantum dots QD1 and the first scattering particle SP1 may be dispersed in the first monomer MN1. In an embodiment, the first monomer MN1 may include an epoxy-based monomer, an ester-based monomer, etc.

The first quantum dot QD1 may convert the color of incident light to blue. For example, the first quantum dot QD1 may be a quantum dot, and may be selected from the group consisting of group II-VI compounds, group IV-VI compounds, group IV elements, group IV compounds, and combinations thereof. However, the first color conversion pattern CT1 may not include the first quantum dot QD1.

The first scattering particle SP1 may scatter light. In an embodiment, the first scattering particle SP1 may include titanium dioxide (TiO₂) particles, zinc oxide (ZnO) particles, aluminum oxide (Al₂O₃) particles, silicon oxide (SiO₂) particles, hollow silica particles, a combination thereof, etc.

The second color conversion pattern CT2 may be disposed on the second color filter RCF. In an embodiment, the second color conversion pattern CT2 may be accommodated by the bank BK.

In an embodiment, the second color conversion pattern CT2 may include a second monomer MN2, a second quantum dot QD2, and a second scattering particle SP2.

The second quantum dot QD2 and the second scattering particle SP2 may be dispersed in the second monomer MN2. In an embodiment, the second monomer MN2 may include an epoxy-based monomer, an ester-based monomer, etc.

The second quantum dot QD2 may convert the color of incident light to red. For example, the second quantum dot QD2 may be a quantum dot, and may be selected from the group consisting of group II-VI compounds, group IV-VI compounds, group IV elements, group IV compounds, and combinations thereof.

The second scattering particle SP2 may scatter light. In an embodiment, the second scattering particle SP2 may include titanium dioxide (TiO₂) particles, zinc oxide (ZnO) particles, aluminum oxide (Al₂O₃) particles, silicon oxide (SiO₂) particles, hollow silica particles, a combination thereof, etc.

The third color conversion pattern CT3 may be disposed on the third color filter GCF. In an embodiment, the third color conversion pattern CT3 may be accommodated by the bank BK.

In an embodiment, the third color conversion pattern CT3 may include a third monomer MN3, a third quantum dot QD3, and a third scattering particle SP3.

The third quantum dot QD3 and the third scattering particle SP3 may be dispersed in the third monomer MN3. In an embodiment, the third monomer MN3 may include an epoxy monomer, an ester monomer, etc.

The third quantum dot QD3 may convert the color of incident light to green. For example, the third quantum dot QD3 may be a quantum dot, and may be selected from the group consisting of group II-VI compounds, group IV-VI compounds, group IV elements, group IV compounds, and combinations thereof.

The third scattering particle SP3 may scatter light. In an embodiment, the third scattering particle SP3 may include titanium dioxide (TiO₂) particles, zinc oxide (ZnO) particles, aluminum oxide (Al₂O₃) particles, silicon oxide (SiO₂) particles, hollow silica particles, a combination thereof, etc.

The capping layer CAP may be disposed on the first to third color conversion patterns CT1, CT2, and CT3. The capping layer CAP may entirely cover the first to third color conversion patterns CT1, CT2, and CT3.

The filler FM may be disposed on the capping layer CAP. In an embodiment, the filler FM may include an organic material having a relatively high refractive index. For example, the filler FM may include urethane resin, epoxy resin, acrylic resin, a combination thereof, etc.

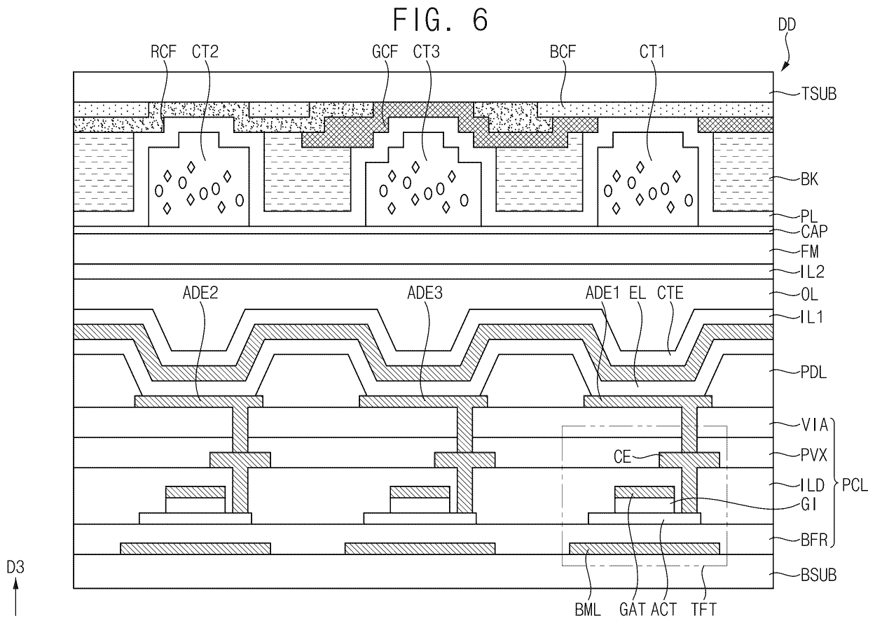

FIG. 6 is a schematic cross-sectional view illustrating the display device of FIG. 1.

Referring to FIG. 6, the display device DD may include the emission substrate 1000 described with reference to FIG. 4 and the color conversion substrate 2000 described with reference to FIG. 5. In an embodiment, the emission substrate 1000 and the color conversion substrate 2000 may be arranged to be aligned with each other. For example, the first color filter BCF may overlap the first pixel electrode ADE1, the second color filter RCF may overlap the second pixel electrode ADE2, and the third color filter GCF may overlap the third pixel electrode ADE3.

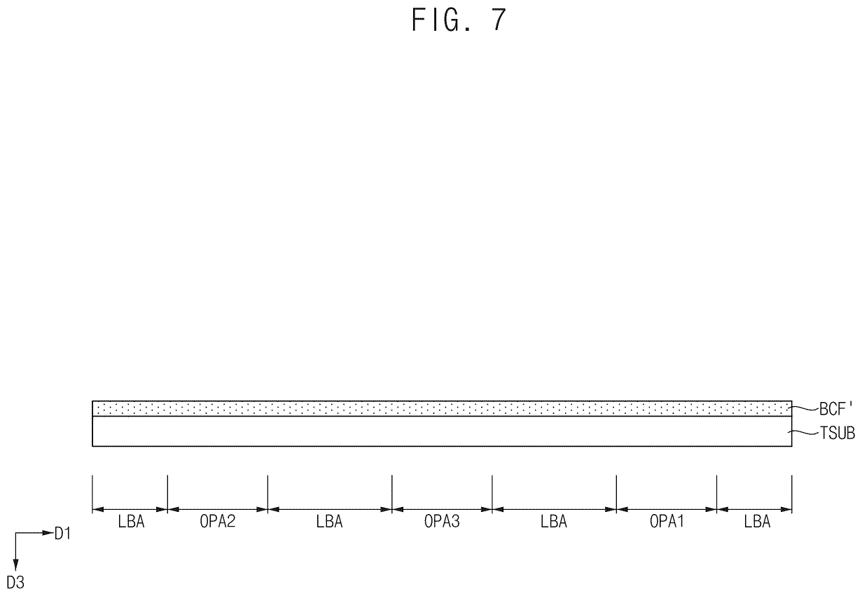

FIGS. 7 to 20 are schematic diagrams illustrating a method of manufacturing the color conversion substrate of FIG. 5.

Referring to FIG. 7, a preliminary first color filter BCF′ may be formed on the upper substrate TSUB. In an embodiment, photoresist may be entirely applied on the upper substrate TSUB. In this disclosure, the photoresist may be described as a negative photoresist, but the disclosure is not limited thereto.

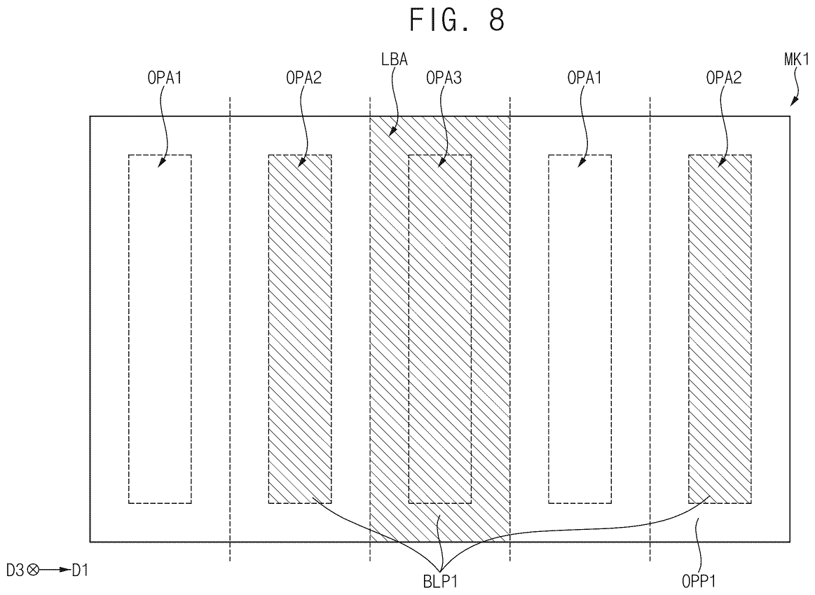

Referring to FIGS. 8, 9, and 10, the first color filter BCF may be formed on the upper substrate TSUB.

In detail, FIG. 8 may illustrate a first mask MK1 for exposing the preliminary first color filter BCF′. As shown in FIG. 8, the first mask MK1 may include a first blocking part BLP1 that blocks light and a first open part OPP1 that allows light to pass. The first blocking part BLP1 may correspond to the second opening area OPA2, the third opening area OPA3, and the light blocking area LBA surrounding the third opening area OPA3 of the upper substrate TSUB. The first open part OPP1 may correspond to an area excluding (or external to) the first blocking part BLP1.

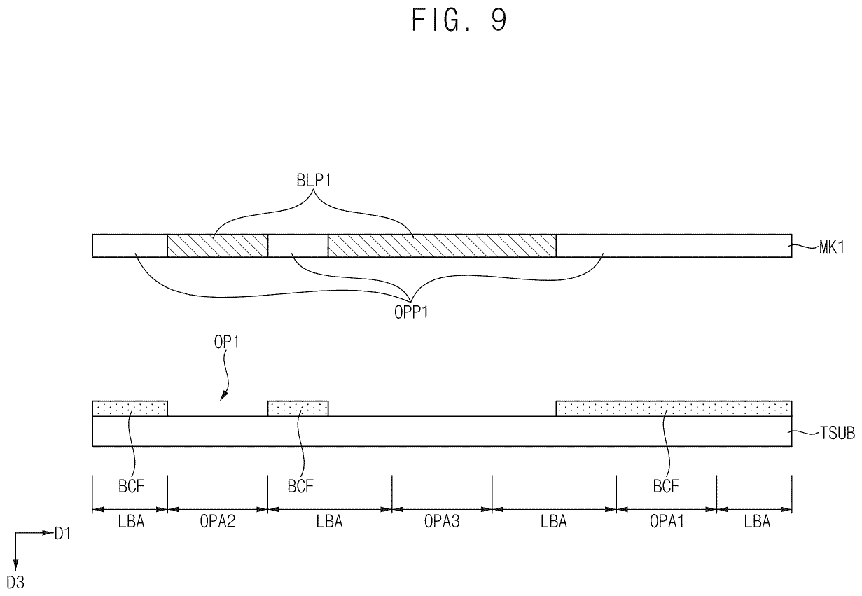

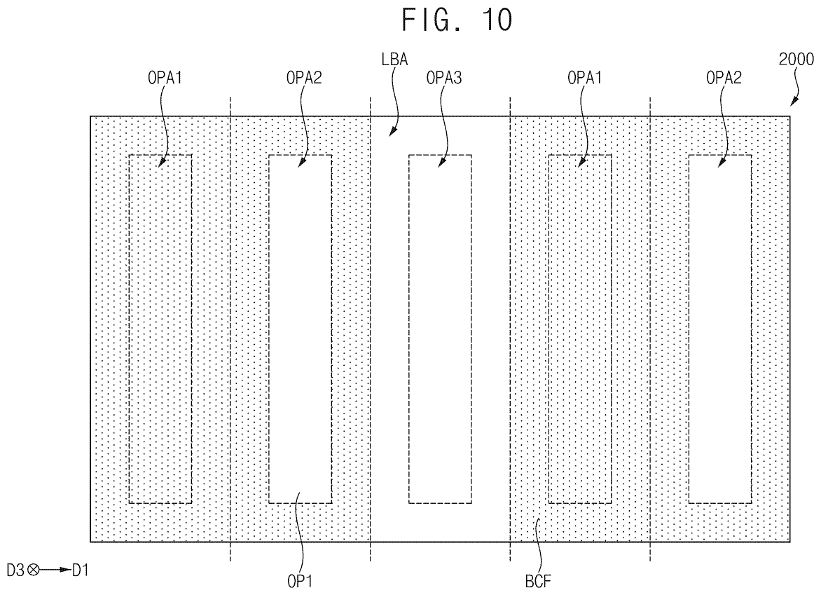

As shown in FIGS. 9 and 10, the first color filter BCF patterned according to the pattern of the first blocking part BLP1 and the first open part OPP1 may be formed.

As the first color filter BCF overlaps the first opening area OPA1, the light emitted from the first opening area OPA1 may have a blue color.

The first color filter BCF may overlap the light blocking area LBA surrounding the second opening area OPA2 and may not be formed in the second opening area OPA2. Accordingly, a first opening OP1 defining the second opening area OPA2 may be formed in the first color filter BCF.

The first color filter BCF may not overlap the light blocking area LBA surrounding the third opening area OPA3. In other words, the first color filter BCF may not define the third opening area OPA3.

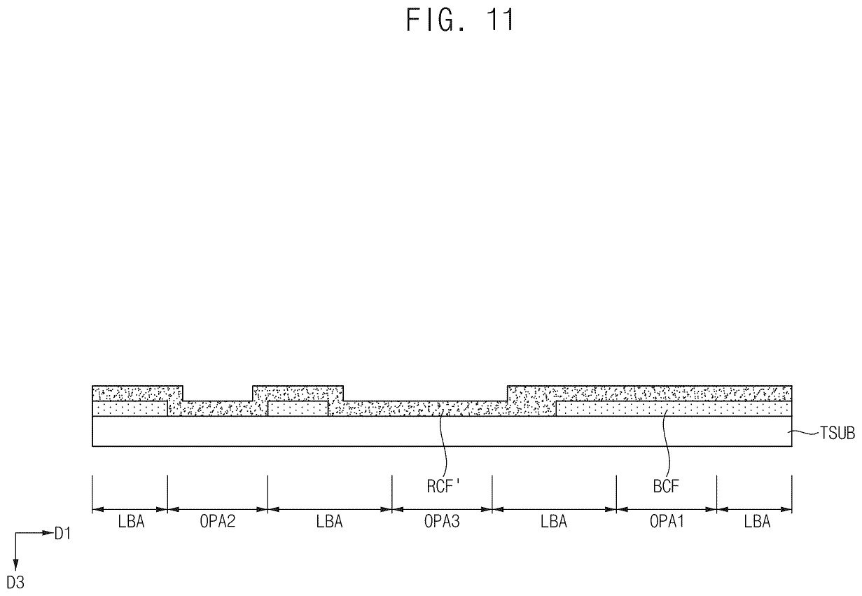

Referring to FIG. 11, a preliminary second color filter RCF′ may be formed on the first color filter BCF. In an embodiment, photoresist may be entirely applied on the first color filter BCF. In this disclosure, the photoresist may be described as a negative photoresist, but the disclosure is not limited thereto.

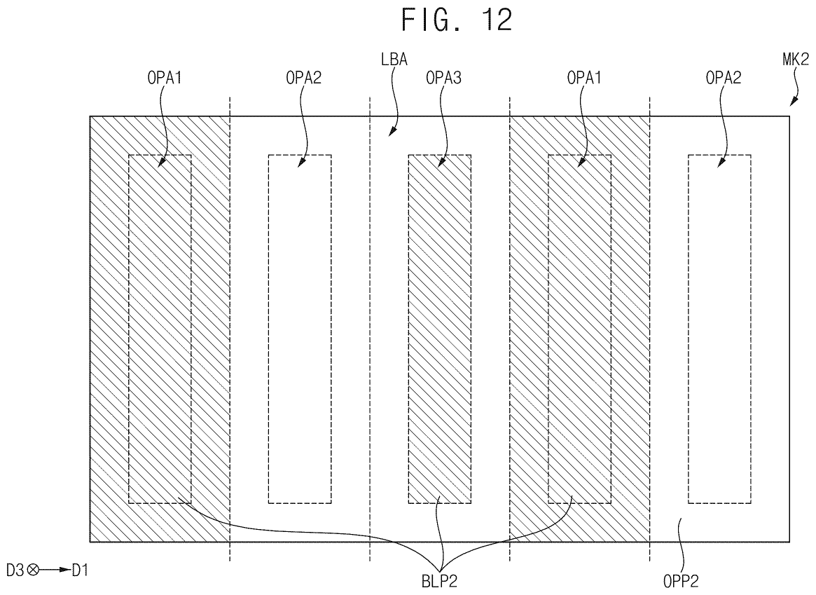

Referring to FIGS. 12, 13, and 14, the second color filter RCF may be formed on the first color filter BCF.

In detail, FIG. 12 may illustrate a second mask MK2 for exposing the preliminary second color filter RCF′. As shown in FIG. 12, the second mask MK2 may include a second blocking part BLP2 that blocks light and a second open part OPP2 that allows light to pass. The second blocking part BLP2 may correspond to the third opening area OPA3, the first opening area OPA1, and the light blocking area LBA surrounding the first opening area OPA1 of the upper substrate TSUB. The second open part OPP2 may correspond to an area excluding the second blocking part BLP2.

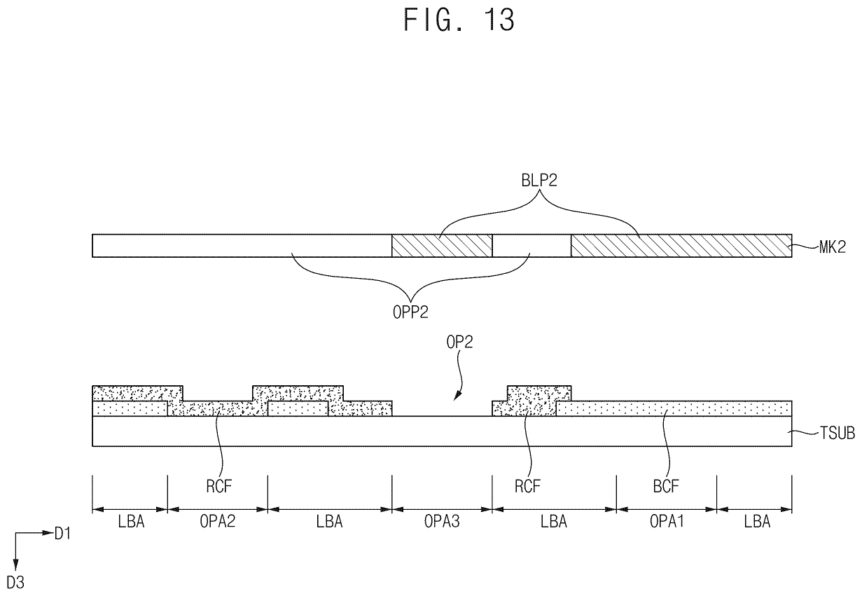

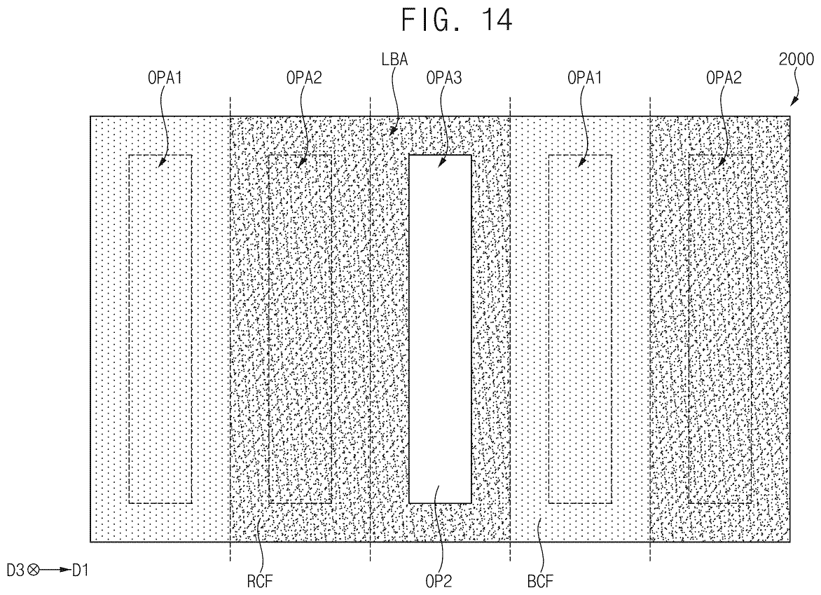

As shown in FIGS. 13 and 14, the second color filter RCF patterned according to the pattern of the second blocking part BLP2 and the second open part OPP2 may be formed.

As the second color filter RCF overlaps the second opening area OPA2, the light emitted from the second opening area OPA2 may have a red color.

The second color filter RCF may overlap the light blocking area LBA surrounding the third opening area OPA3 and may not be formed in the third opening area OPA3. Accordingly, a second opening OP2 defining the third opening area OPA3 may be formed in the second color filter RCF.

The second color filter RCF may not overlap the light blocking area LBA surrounding the first opening area OPA1. In other words, the second color filter RCF may not define the first opening area OPA1.

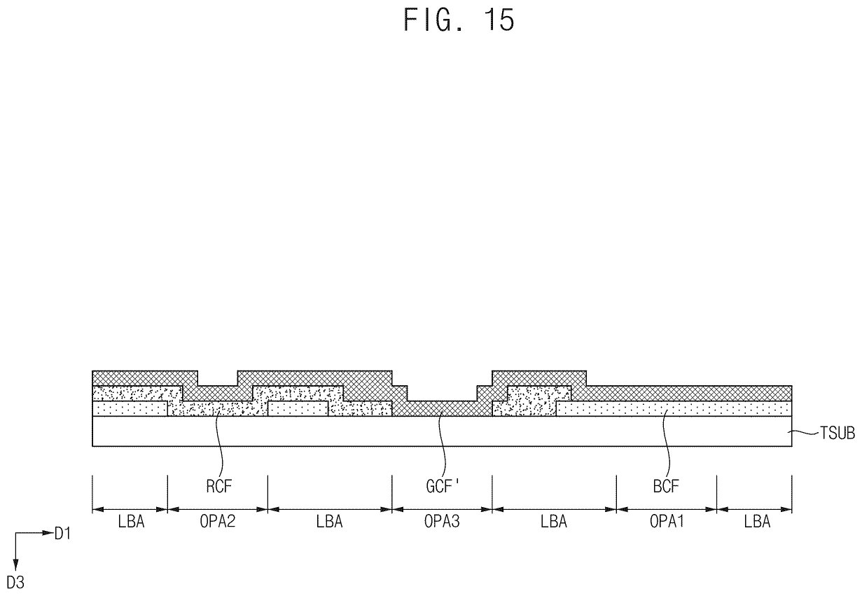

Referring to FIG. 15, a preliminary third color filter GCF′ may be formed on the second color filter RCF. In an embodiment, photoresist may be entirely applied on the second color filter RCF. In this disclosure, the photoresist may be described as a negative photoresist, but the disclosure is not limited thereto.

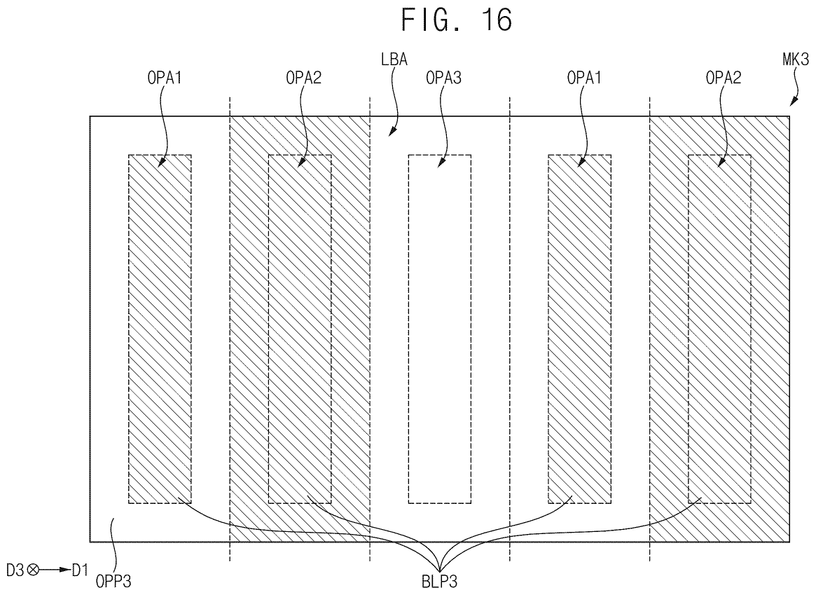

Referring to FIGS. 16, 17, and 18, the third color filter GCF may be formed on the second color filter RCF.

In detail, FIG. 16 may illustrate a third mask MK3 for exposing the preliminary third color filter GCF′. As shown in FIG. 16, the third mask MK3 may include a third blocking part BLP3 that blocks light and a third open part OPP3 that allows light to pass. The third blocking part BLP3 may correspond to the first opening area OPA1, the second opening area OPA2, and the light blocking area LBA surrounding the second opening area OPA2 of the upper substrate TSUB. The third open part OPP3 may correspond to an area excluding the third blocking part BLP3.

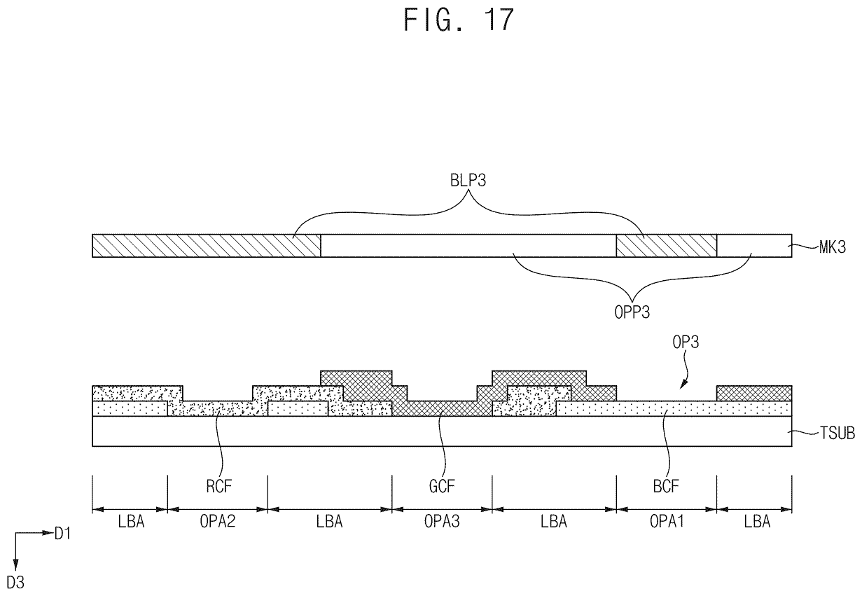

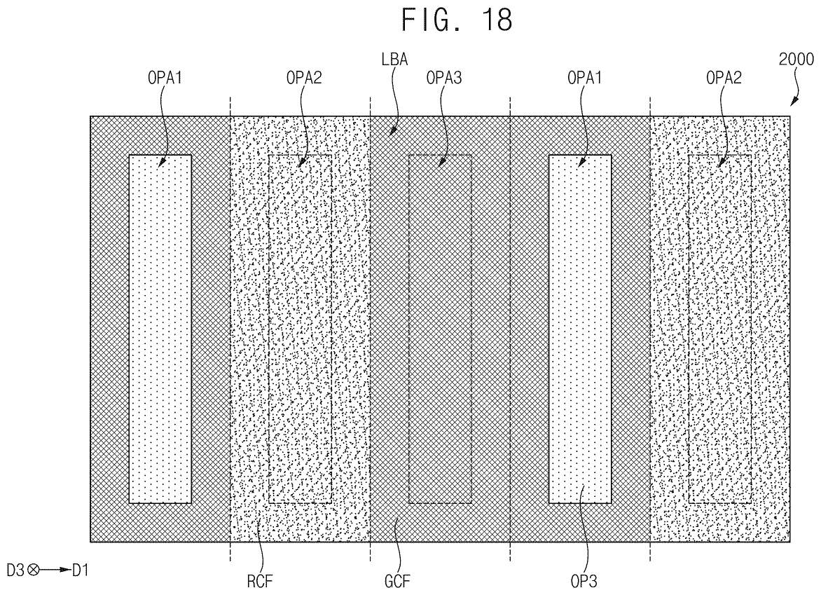

As shown in FIGS. 17 and 18, the third color filter GCF patterned according to the pattern of the third blocking part BLP3 and the third open part OPP3 may be formed.

As the third color filter GCF overlaps the third opening area OPA3, the light emitted from the third opening area OPA3 may have a green color.

The third color filter GCF may overlap the light blocking area LBA surrounding the first opening area OPA1 and may not be formed in the first opening area OPA1. Accordingly, a third opening OP3 defining the first opening area OPA1 may be formed in the third color filter GCF.

The third color filter GCF may not overlap the light blocking area LBA surrounding the second opening area OPA2. In other words, the third color filter GCF may not define the second opening area OPA2.

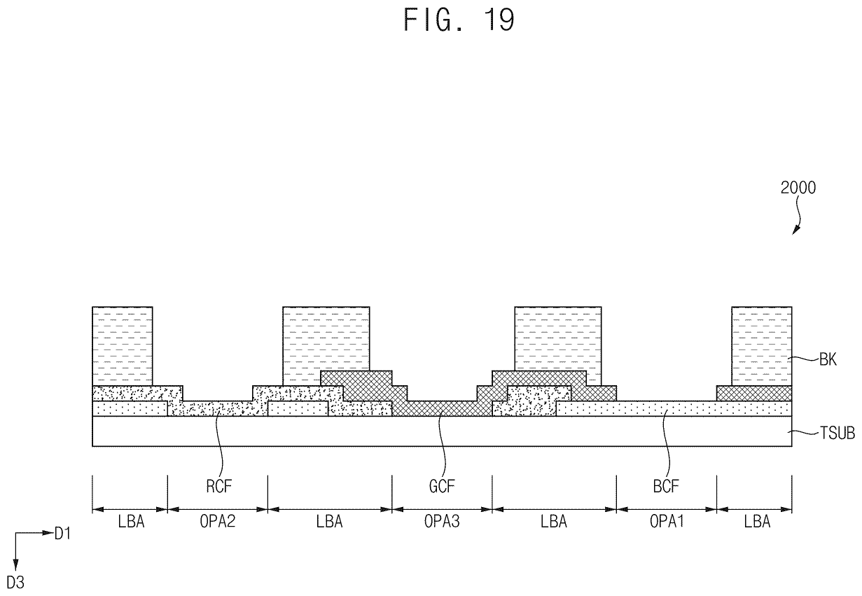

Referring to FIG. 19, the bank BK may be disposed on the upper substrate TSUB and may overlap the light blocking area LBA. In an embodiment, the bank BK may be disposed on the third color filter GCF, and may overlap at least two color filters among the first to third color filters BCF, RCF, and GCF. In an embodiment, the bank BK may be disposed on the second color filter RCF and may overlap at least one color filter among the first and second color filters BCF and RCF.

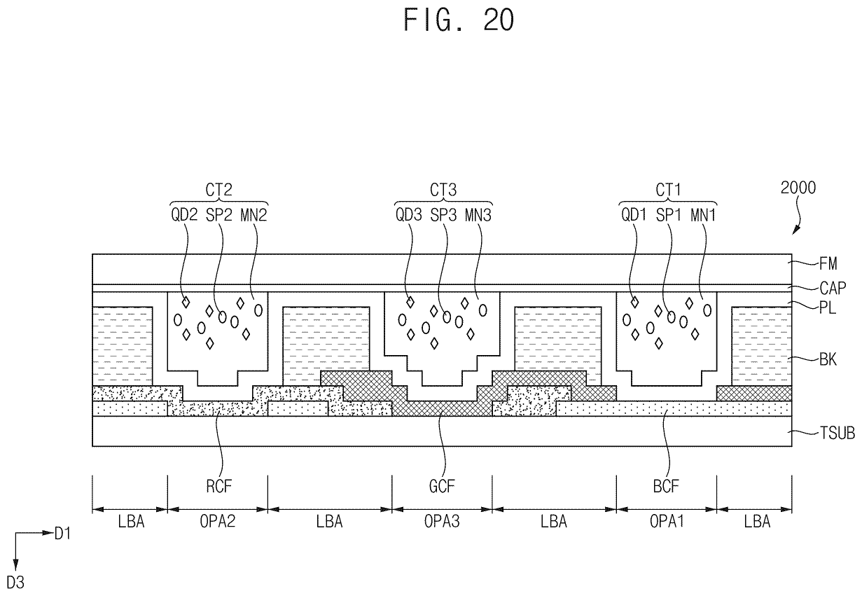

Referring to FIG. 20, the protective layer PL, the first to third color conversion patterns CT1, CT2, and CT3, the capping layer CAP, and the filler FM may be sequentially formed on the bank BK.

According to the color conversion substrate 2000 according to an embodiment of the disclosure, the color filter may define only one adjacent opening area and not define another opening area. For example, the first color filter BCF may define the second opening area OPA2 and may not define the third opening area OPA3. The second color filter RCF may define the third opening area OPA3 and may not define the first opening area OPA1. The third color filter GCF may define the first opening area OPA1 and may not define the second opening area OPA2. Accordingly, a margin for the width WBK of the bank BK in the first direction D1 may be secured, and the pitch between the first to third opening areas OPA1, OPA2, and OPA3 may be reduced. Accordingly, the resolution of the display device DD including the color conversion substrate 2000 can be improved.

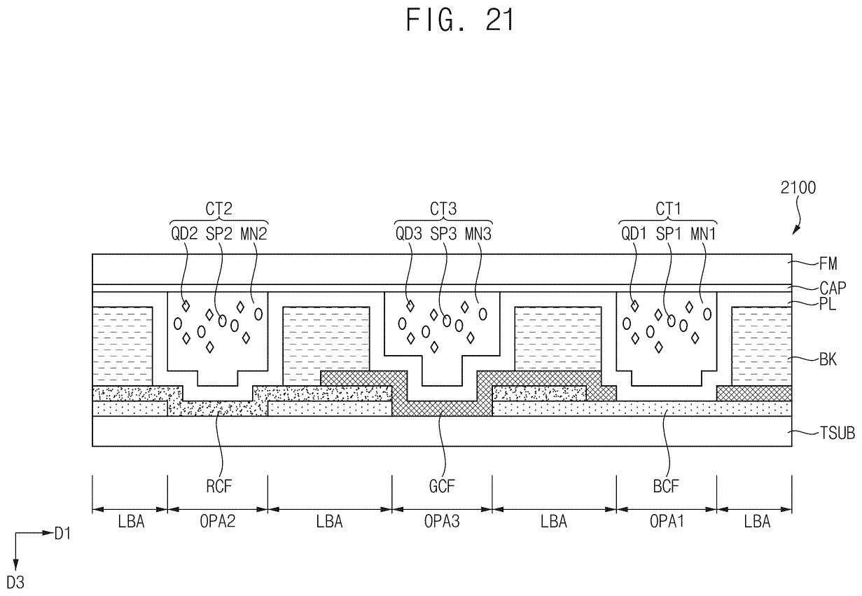

FIG. 21 is a schematic cross-sectional view illustrating a color conversion substrate included in a display device according to an embodiment of the disclosure.

FIG. 21 illustrate that a color conversion substrate 2100 included in a display device according to an embodiment of the disclosure may include first to third color filters BCF, RCF, and GCF.

The first color filter BCF may be disposed on the upper substrate TSUB, may overlap the first opening area OPA1, and may define the second opening area OPA2 and the third opening area OPA3. In other words, the first color filter BCF may define two adjacent opening areas.

The second color filter RCF may be disposed on the first color filter BCF, may overlap the second opening area OPA2, and may define the third opening area OPA3 and may not define the first opening area OPA1. In other words, the second color filter RCF may define only one adjacent opening area and may not define another opening area.

The third color filter GCF may be disposed on the second color filter RCF, may overlap the third opening area OPA3, may define the first opening area OPA1, and may not define the second opening area OPA2. In other words, the third color filter GCF may define only one adjacent opening area and may not define another opening area.

According to the color conversion substrate 2100 according to an embodiment of the disclosure, the color filter formed at the bottom may define two adjacent opening areas. For example, the first color filter BCF may define a second opening area OPA2 and a third opening area OPA3. Each of the different color filters may define only one adjacent opening area and may not define another opening area. For example, the second color filter RCF may define the third opening area OPA3 and may not define the first opening area OPA1. The third color filter GCF may define the first opening area OPA1 and may not define the second opening area OPA2. Accordingly, a margin for the width WBK of the bank BK in the first direction D1 may be secured, and the pitch between the first to third opening areas OPA1, OPA2, and OPA3 may be reduced. Accordingly, the resolution of the display device including the color conversion substrate 2100 can be improved.

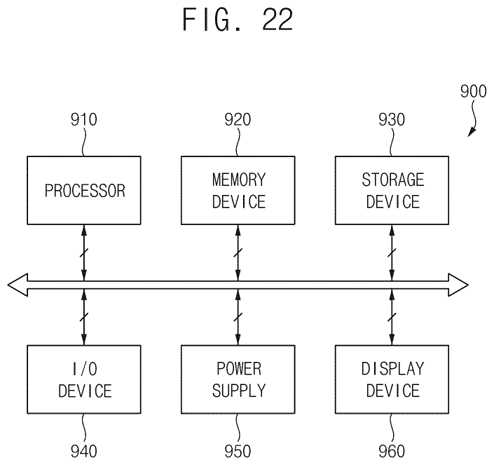

FIG. 22 is a block diagram illustrating an electronic device according to an embodiment of the disclosure.

Referring to FIG. 22, in an embodiment, an electronic device 900 may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although certain embodiments and implementations have been described herein, other embodiments and modifications will be apparent from this disclosure. Accordingly, the disclosure is not limited to such embodiments, but rather to the broader scope of the appended claims and various obvious modifications and equivalent arrangements as would be apparent to a person of ordinary skill in the art.

What is claimed is:

1. A color conversion substrate comprising:
an upper substrate including a first opening area, a second opening area adjacent to the first opening area, and a third opening area adjacent to the second opening area;
a first color filter disposed on the upper substrate and having a first opening which defines the second opening area;
a second color filter disposed on the first color filter and having a second opening which defines the third opening area; and
a third color filter disposed on the second color filter and having a third opening which defines the first opening area,
wherein the first color filter does not overlap a light blocking area surrounding the third opening area.

2. The color conversion substrate of claim 1, wherein the first color filter overlaps a light blocking area surrounding the second opening area.

3. The color conversion substrate of claim 1, wherein the first color filter overlaps the first opening area and a light blocking area surrounding the first opening area.

4. The color conversion substrate of claim 1, wherein the second color filter does not overlap a light blocking area surrounding the first opening area.

5. The color conversion substrate of claim 4, wherein the second color filter overlaps a light blocking area surrounding the third opening area.

6. The color conversion substrate of claim 4, wherein the second color filter overlaps the second opening area and a light blocking area surrounding the second opening area.

7. The color conversion substrate of claim 1, wherein the third color filter does not overlap a light blocking area surrounding the second opening area.

8. The color conversion substrate of claim 7, wherein the third color filter overlaps a light blocking area surrounding the first opening area.

9. The color conversion substrate of claim 7, wherein the third color filter overlaps the third opening area and a light blocking area surrounding the third opening area.

10. The color conversion substrate of claim 1, wherein the first, second, and third opening areas are arranged side by side.

11. The color conversion substrate of claim 1, wherein
the first color filter is a blue color filter,
the second color filter is a red color filter, and
the third color filter is a green color filter.

12. The color conversion substrate of claim 1, further comprising:
a bank disposed on the upper substrate and overlapping a light blocking pattern surrounding the first to third opening areas.

13. The color conversion substrate of claim 12, further comprising:
a first color conversion pattern disposed on the first color filter, the first color conversion pattern accommodated by the bank and including first quantum dots;
a second color conversion pattern disposed on the second color filter, the second color conversion pattern accommodated by the bank and including second quantum dots; and
a third color conversion pattern disposed on the third color filter, the third color conversion pattern accommodated by the bank and including third quantum dots.

14. A display device comprising:
an emission substrate and a color conversion substrate disposed on the emission substrate, wherein
the emission substrate includes:
a lower substrate;
a first pixel electrode disposed on the lower substrate;
a second pixel electrode disposed on the lower substrate and adjacent to the first pixel electrode; and
a third pixel electrode disposed on the lower substrate and adjacent to the second pixel electrode,
the color conversion substate includes:
an upper substrate including a first opening area, a second opening area adjacent to the first opening area, and a third opening area adjacent to the second opening area;
a first color filter disposed between the lower substrate and the upper substrate, the first color filter having a first opening which defines the second opening area;
a second color filter disposed between the first color filter and the lower substrate, the second color filter having a second opening which defines the third opening area; and
a third color filter disposed between the second color filter and the lower substrate, the third color filter having a third opening which defines the first opening area, and
the first color filter does not overlap a light blocking area surrounding the third opening area.

15. The display device of claim 14, wherein the first color filter overlaps a light blocking area surrounding the second opening area.

16. The display device of claim 14, wherein the first color filter overlaps the first opening area and a light blocking area surrounding the first opening area.

17. The display device of claim 14, wherein the second color filter does not overlap a light blocking area surrounding the first opening area.

18. The display device of claim 14, wherein
the first color filter overlaps the first pixel electrode,
the second color filter overlaps the second pixel electrode, and
the third color filter overlaps the third pixel electrode.

19. The display device of claim 14, further comprising:
an emission layer disposed on the first to third pixel electrodes; and
a common electrode disposed on the emission layer.

20. The display device of claim 14, further comprising:
an active pattern disposed on the lower substrate;
a gate electrode disposed on the active pattern; and
a connection electrode disposed on the gate electrode and electrically connected to the active pattern.

21. An electronic device comprising:
a display device; and
a power supply configured to provide power to the display device,
wherein the display device comprises:
an emission substrate and a color conversion substrate disposed on the emission substrate, wherein
the emission substrate includes:
a lower substrate;
a first pixel electrode disposed on the lower substrate;
a second pixel electrode disposed on the lower substrate and adjacent to the first pixel electrode; and
a third pixel electrode disposed on the lower substrate and adjacent to the second pixel electrode,
the color conversion substate includes:
an upper substrate including a first opening area, a second opening area adjacent to the first opening area, and a third opening area adjacent to the second opening area;
a first color filter disposed between the lower substrate and the upper substrate, the first color filter having a first opening which defines the second opening area;
a second color filter disposed between the first color filter and the lower substrate, the second color filter having a second opening which defines the third opening area; and
a third color filter disposed between the second color filter and the lower substrate, the third color filter having a third opening which defines the first opening area, and
the first color filter does not overlap a light blocking area surrounding the third opening area.
